(19) United States
(12) Patent Application Publication
(10) Pub. No.: US 2022/0375870 A1
(43) Pub. Date: Nov. 24, 2022

(54) GAP-FILL FOR 3D NAND STAIRCASE

(71) Applicant: Intel NDTM US LLC, SANTA CLARA, CA (US)

(72) Inventors: Jung Chan Lee, SAN JOSE, CA (US); Agus Tjandra, Milpitas, CA (US); Ebony Mays, Morgan Hill, CA (US)

(21) Appl. No.: 17/817,857

(22) Filed: Aug. 5, 2022

(51) Int. Cl. H01L 23/532; H01L 23/535; H01L 27/11556; H01L 27/11582

(52) U.S. Cl. CPC H01L 23/53295; H01L 23/535; H01L 27/11556; H01L 27/11582

(57) ABSTRACT

Systems, apparatuses, and methods may provide for technology that gap-fills stairwells for memory devices. The memory device is manufactured by forming a liner film on a trench of a stairwell layer of the memory device; depositing a doped silicon dioxide film on the liner film, wherein doping of the doped silicon dioxide film is performed during the deposition; and performing a pressurized and steamed anneal on the doped silicon dioxide film deposited on the liner film to form a reflowed doped silicon dioxide film.

### TECHNICAL FIELD

Embodiments generally relate to memory structures. More particularly, embodiments relate to a gap-fill techniques for staircase structures utilized in memory.

### BACKGROUND

Three-dimensional (3D) NAND technologies are commonly used to create nonvolatile (NV) storage devices, such as solid state drives (SSDs). Reference to 3D NAND can more specifically refer to NAND flash.

NAND-type flash memory (“NAND memory”) may be organized into multiple cells, with each cell containing one or more bits of data and being accessible through an array of bit lines (columns) and word lines (rows). With 3D NAND processes, the storage array is often created with the word lines (WL) in a staircase structure, with vertical connector pillars connecting a top connection layer to the word lines.

Increased 3D NAND densities are achieved with smaller process geometries and feature spacing. With the increase of number of tiers or word lines in 3D NAND in every generation, the number of WL contacts is also going up, requiring more routing paths to hook up the word line contacts to corresponding complementary metal-oxide-semiconductor (CMOS) devices.

Gap-fill operations in staircase implementations of 3D NAND face increasing challenges. For example, such increasing challenges for gap-fill operations may be due to high aspect ratio and large volumes of trenches being filled. More particularly, staircase gap-fill trench aspect ratio may increase due to one or more of the following: 1) staircase design changes from a serial layout to a parallel layout, 2) trench height increases as a result of increasing the number of tiers, and/or 3) integration changes such as a con3 (e.g., CMOS area contacts (CON3 in this case)) elimination scheme.

### BRIEF DESCRIPTION OF THE DRAWINGS

The various advantages of the embodiments will become apparent to one skilled in the art by reading the following specification and appended claims, and by referencing the following drawings, in which:

FIG. 1 is a block diagram of an example of a multi-deck non-volatile memory device according to an embodiment;

FIG. 2 illustrates an example side view diagram of a memory die according to an embodiment;

FIG. 3 is a block diagram of an example existing memory device according to an embodiment;

FIG. 4 is a block diagram of an example memory device according to an embodiment;

FIG. 5 is a perspective view of an existing staircase area;

FIG. 6 is a perspective view of a staircase area according to an embodiment;

FIG. 7 is a flowchart of an example of another method of forming a memory device according to an embodiment;

FIG. 8 is a block diagram of an example memory device formed via a conventional anneal process;

FIG. 9 is a block diagram of an example memory device after deposition according to an embodiment;

FIG. 10 is a block diagram of an example memory device formed via a pressurized anneal process according to an embodiment;

FIG. 11 is an illustration of an example of a semiconductor package apparatus according to an embodiment; and

FIG. 12 is a block diagram of an example of a performance-enhanced computing system according to an embodiment.

### DESCRIPTION OF EMBODIMENTS

As described above, gap-fill operations in staircase implementations of 3D NAND face increasing challenges due to high aspect ratio and large volumes of trenches being filled. Disadvantageously, such an aspect ratio increase of a gap-fill trench will typically cause significant gap-fill scheme complexity, which will increase gap-fill cost, defect and decrease process window.

On existing gap-fill technique involves performing a plasma-enhanced chemical vapor deposition of TEOS (PETEOS) in conjunction with a spin-on dielectric (SOD) coating, which is followed by an anneal in conjunction with another PETEOS deposition (e.g., which can be referred to as s Dep-SOD/anneal-Dep scheme). Such a Dep-SOD/anneal-Dep scheme typically causes significant SOD non-uniformity and defects (such as non-uniform fill of SOD in differently sized structures and film cracking on topo wafers). Additionally, such a Dep-SOD/anneal-Dep scheme typically increases costs due to the need for increased deposition cycles with increased fill volumes and at downstream integration due to issues with planarization of the resulting over burden (e.g., chemical mechanical polishing (CMP)) and/or due to high over burden deltas of gap-fill materials over the array area versus the staircase area in response to a total gap-fill thickness increase.

Another existing gap-fill technique involves sequentially performing a deposition, forming a photoresist (PR) coating, performing a PR etch back, and performing an oxide (OX) etch back, where a deposition cycle may be performed via a cyclic process (e.g., with 2-4 times of cycling) are typically used to improve gap-fill performance and address defects. Such a PR technique (e.g., including performance of electron-beam lithography (EB)) performed through a multiple cyclic scheme (e.g., a Deposition—PR coating—PR Etch back—Ox Etch back—Deposition cycle scheme) showed significant cost increase due to the use of such a complex process flow multiple times. In addition, there may be a potential concern of a gap-fill performance degradation as well as a defect increase (e.g., including structure damage) by the etch back process and defect formation during such multiple deposition processes.

As will be descried in greater detail below, systems, apparatuses, and methods described herein may provide for technology that advantageously addresses one or more of the following: 1) a gap-fill performance improvement that is less sensitive to structure shape/profile, 2) a cost reduction with a one-step gap-fill solution along with a reduction in deposition thickness, and/or 3) a minimal CMOS performance impact while using a relatively lower anneal temperature.

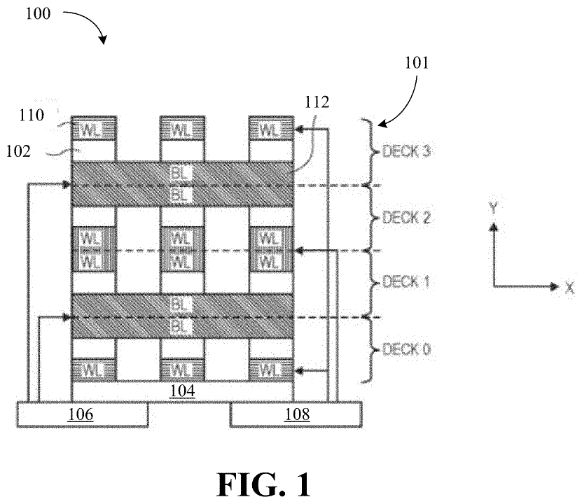

FIG. 1 is a simplified block diagram of an example of a memory device 100 according to an embodiment. As illustrated, the memory device 100 is a multi-deck non-volatile memory device including a plurality of decks 101 (e.g., Deck 0, Deck 1, Deck 2, and Deck 3, or the like).

In some implementations, each of the decks 101 may include an array of memory cells 102 with conductive access lines (e.g., word lines 110 and bitlines 112). For example, the memory cells 102 may include a material capable of being in two or more stable states to store a logic value. In one example, the memory cells 102 may include a phase change material, a chalcogenide material, the like, or combinations thereof. However, any suitable storage material may be utilized. The word lines 110 and bitlines 112 may be patterned so that the word lines 110 are orthogonal to the bitlines 112, creating a grid pattern or “cross-points.” A cross-point is an intersection between a bitline, a word line, and active material(s) (e.g., a selector and/or a storage material). A memory cell 102 may be located at the intersection of a bitline 112 and a word line 110. Accordingly, one or more of the decks 101 may include a crosspoint array of non-volatile memory cells, where each of the memory cells may include a material capable of being in two or more stable states to store a logic value.

As illustrated, an electrically isolating material 104 may separate the conductive access lines (e.g., word lines 110 and bitlines 112) of the bottom deck (e.g., deck 0) from bitline sockets 106 and word line sockets 108. For example, the memory cells 102 may be coupled with access and control circuitry for operation of the three-dimensional memory device 100 via the bitline sockets 106 and the word line sockets 108.

Examples of multi-deck or multi-layer memory architectures include multi-deck crosspoint memory and 3D NAND memory. Different memory technologies have adopted different terminology. For example, a deck in a crosspoint memory device typically refers to a layer of memory cell stacks that can be individually addressed. In contrast, a 3D NAND memory device is typically said to include a NAND array that includes many layers, as opposed to decks. In 3D NAND, a deck may refer to a subset of layers of memory cells (e.g., two decks of X-layers to effectively provide a 2X-layer NAND device). The term “deck” will be used throughout this disclosure to describe a layer, a tier, or a similar portion of a three-dimensional memory.

The memory device 100 may include non-volatile memory and/or volatile memory. Non-volatile memory is a storage medium that does not require power to maintain the state of data stored by the medium. In one embodiment, the memory structure is a block addressable storage device, such as those based on NAND or NOR technologies. A storage device may also include future generation nonvolatile devices, such as a three-dimensional (3D) crosspoint memory device, or other byte addressable write-in-place nonvolatile memory devices. In one embodiment, the storage device may be or may include memory devices that use silicon-oxide-nitride-oxide-silicon (SONOS) memory, electrically erasable programmable read-only memory (EEPROM), chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thiristor based memory device, or a combination of any of the above, or other memory. The term “storage device” may refer to the die itself and/or to a packaged memory product. In some embodiments, 3D crosspoint memory may comprise a transistor-less stackable cross point architecture in which memory cells sit at the intersection of word lines and bit lines and are individually addressable and in which bit storage is based on a change in bulk resistance. In particular embodiments, a memory module with non-volatile memory may comply with one or more standards promulgated by the Joint Electron Device Engineering Council (JEDEC), such as JESD235, JESD218, JESD219, JESD220-1, JESD223B, JESD223-1, or other suitable standard (the JEDEC standards cited herein are available at jedec.org).

Volatile memory is a storage medium that requires power to maintain the state of data stored by the medium. Examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular embodiments, DRAM of the memory modules complies with a standard promulgated by JEDEC, such as JESD79F for Double Data Rate (DDR) SDRAM, JESD79-2F for DDR2 SDRAM, JESD79-3F for DDR3 SDRAM, or JESD79-4A for DDR4 SDRAM (these standards are available at jedec.org). Such standards (and similar standards) may be referred to as DDR-based standards and communication interfaces of the storage devices that implement such standards may be referred to as DDR-based interfaces.

The memory device 100 may include non-volatile memory and/or volatile memory. Non-volatile memory is a storage medium that does not require power to maintain the state of data stored by the medium. In one embodiment, the memory structure is a block addressable storage device, such as those based on NAND or NOR technologies. A storage device may also include future generation nonvolatile devices.

The techniques described herein typically may not be limited to crosspoint memory but may be applied to other memory devices as well, including memory devices with one or multiple layers or multiple decks of memory cells.

As will be described in greater detail below, systems, apparatuses and methods of some implementations herein advantageously provide for technology that enables a void/seam free one-step gap-fill solution at high aspect ratio that can be utilized in a trench, which may have a large volume.

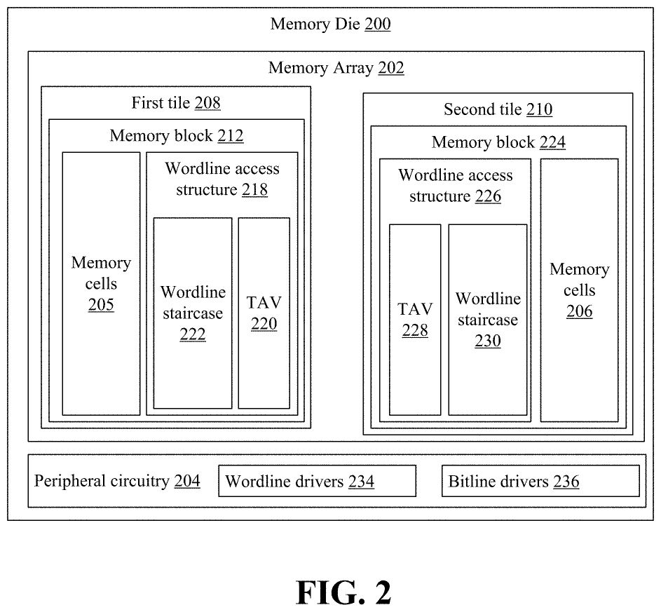

FIG. 2 illustrates a simplified example side view diagram of a memory die 200, consistent with one embodiment of the present disclosure. The memory die 200 includes a 3D flash memory architecture and utilizes a word line bridge to share word line access structures between two tiles of a memory array, for example.

The memory die 200 includes a memory array 202 and peripheral circuitry 204, according to one embodiment. The memory array 202 includes memory cells 205 and memory cells 206 that are accessed (e.g., read/write) with the peripheral circuitry 204, according to one embodiment. The peripheral circuitry 204 is fabricated at least partially under the memory array 202 in the memory die 200, for example, using CMOS under the array fabrication techniques, for example.

The memory array 202 is segmented into a first tile 208 and a second tile 210, according to one embodiment. Although two tiles are illustrated and described the memory array 202 may be segmented into 10's or 100's of tiles to facilitate access and operation of the memory array 202, according to one embodiment. The first tile 208 includes a memory block 212, which includes the memory cells 205 and word line access structures 218, according to one embodiment. The word line access structures 218 include through array vias 220 and a word line staircase 222, according to one embodiment. The through array vias 220 connect word lines for the memory cells 205 to the peripheral circuitry 204, under the memory array 202, according to one embodiment. The word line staircase 222 represents a word line staircase structure that may be used to connect the word lines of the memory cells 205 to metal contacts for connection to upper metal levels, according to one embodiment. The word line access structures 218 are illustrated disproportionately large in comparison to the memory cells 205 for illustration purposes. In practice, the memory cells 205 may occupy a significantly larger area in the memory array that the word line access structures 218, for example.

The second tile 210 includes a memory block 224, which includes the memory cells 206 and word line access structures 226, according to one embodiment. The word line access structures 226 include through array vias 228 and a word line staircase 230, according to one embodiment. The through array vias 228 pass through the memory block 224 to couple upper metal levels to the peripheral circuitry 204, according to one embodiment. The word line staircase 230 provides landings and/or a structure to which metal contacts connect the word lines of the memory cells 206 to upper metal levels that are on top of or above the memory array 202, for example.

The peripheral circuitry 204 includes word line drivers 234 and bitline drivers 236 that drive word lines and bitlines for the memory array 202, for example.

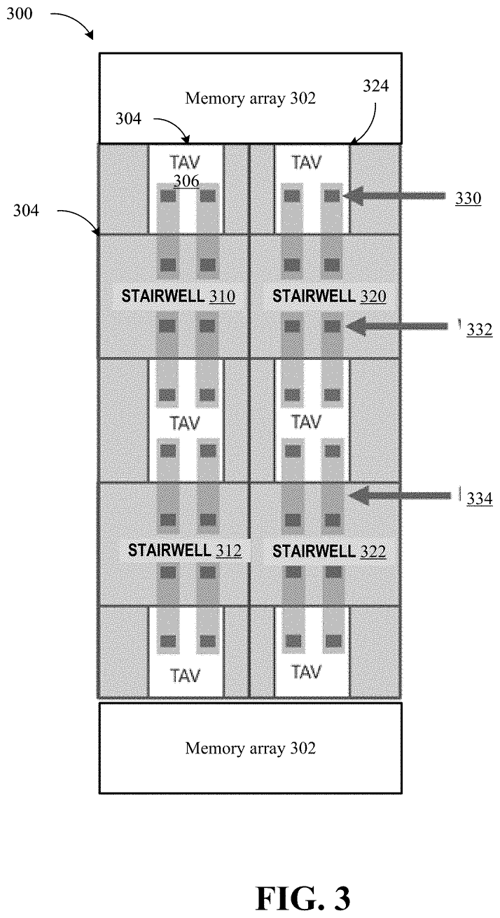

FIG. 3 is a block diagram of an example serial layout memory device 300. As will be described in greater detail below, serial layout memory device 300 is typically limited to a total of two stairwells per memory block. Further, every stairwell typically has word line contacts landing on each and every deck (e.g., all three decks in some implementations). Additionally, the stairwells and through array vias (TAV) are placed in serial positions.

As illustrated, the serial layout memory device 300 includes a memory array 302 and a memory block 304 coupled to the memory array 302. Each memory block (e.g., memory block 304 and memory block 324) is typically limited to a total of two stairwells (e.g., stairwells 310/312 for memory block 304 and stairwells 320/322 for memory block 324) per memory block.

A plurality of metal routers 334 individually connect a plurality of word line contacts 432 to a plurality of string driver contacts 430. As illustrated, every stairwell typically has word line 332 contacts landing on each and every deck (e.g., all three decks in some implementations). Additionally, the stairwells and through array vias (e.g., TAVs 306) are placed in serial positions (e.g., where a stairwell is interspersed between each sequential pair of TAVs).

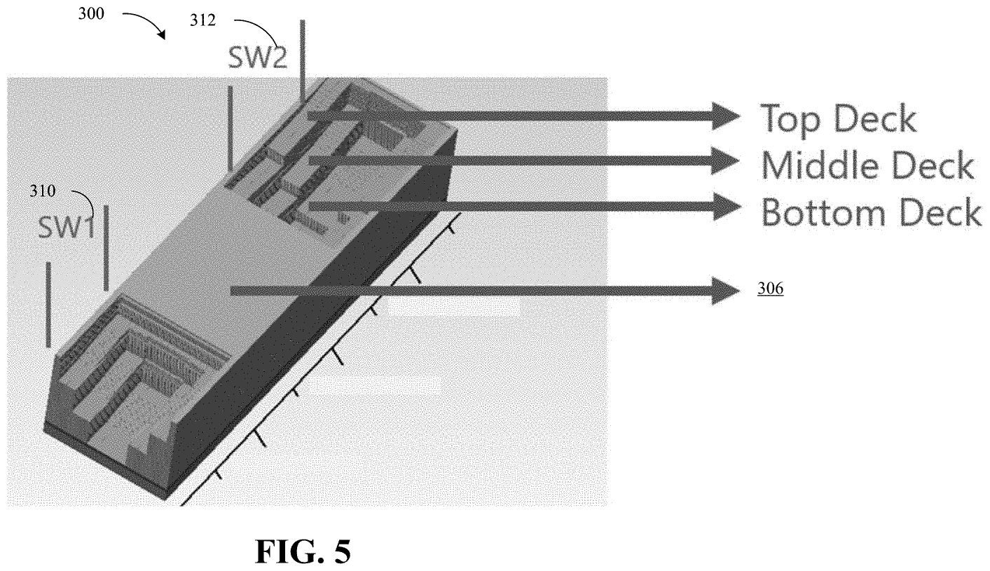

Additional details regarding the serial layout memory device 300 are discussed below with respect to FIG. 5

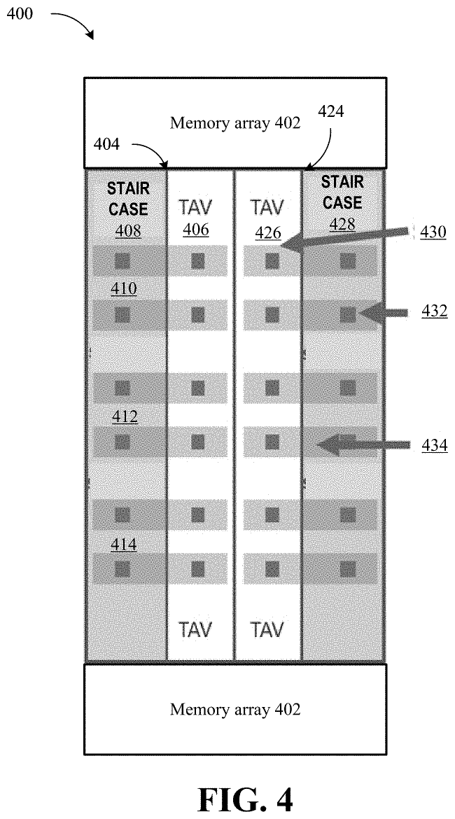

FIG. 4 is a block diagram of a parallel layout memory device 400. As will be described in greater detail below, the parallel layout memory device 400 differs from the serial layout memory device 300 in several ways. For example, the parallel layout memory device 400 typically includes more than two stairwells (e.g., three stairwells in the illustrated example). Further, the plurality of stairwells have word line contacts that typically land on only one deck (e.g., one stairwell per deck). Additionally, the stairwells and through array vias (TAV) are typically placed side-by-side in parallel position.

As illustrated, the parallel layout memory device 400 includes a memory array 402 and a memory block 404 coupled to the memory array 402.

In the illustrated example, the memory block includes a first through array via area 406 and a first staircase area 408. The first staircase area 408 is coupled to a plurality of decks (e.g., Deck, 0, Deck 1, etc. of FIG. 1) and positioned adjacent to the first through array via area 406.

The first staircase area 408 includes a first stairwell 410 and a second stairwell 412 located contiguous to the first stairwell 410. For example, the first staircase area 408 comprises a third stairwell 414 located contiguous to the first stairwell 410 and the second stairwell 412.

In some examples, the first stairwell 410 is coupled exclusively to a first one of the plurality of decks (e.g., Deck 0 of FIG. 1). In such an example, the second stairwell 412 is coupled exclusively to a second one of the plurality of decks (e.g., Deck 1 of FIG. 1). The second stairwell 412 is a different stairwell than the first stairwell 410 and the second one of the plurality of decks (e.g., Deck 1 of FIG. 1) is a different deck than the first one of the plurality of decks. (e.g., Deck 0 of FIG. 1).

In some implementations, the parallel layout memory device 400 includes a second memory block 424 coupled to the memory array 402. The second memory block 424 includes a second through array via area 426 and a second staircase area 428. In such an implementation, the second staircase area 428 is coupled to the plurality of decks (e.g., Deck, 0, Deck 1, etc. of FIG. 1) and positioned adjacent to the second through array via area 426.

In some examples, the first and second staircase areas 408/428 and the first and second through array via areas 406/426 form a sandwich structure. Such a sandwich structure has the first and second staircase areas 408/428 located on an outside of the sandwich and the first and second through array via areas 406/426 positioned adjacent one another on an inside of the sandwich.

Similarly, in some implementations, the first and second staircase areas 408/428 and the first and second through array via areas 406/426 extend parallel to one another and perpendicular to the memory array 402.

In some examples, the first through array via area 406 comprises a plurality of string driver contacts 430 and the first staircase area 408 comprises a plurality of word line contacts 432. In such an example a plurality of metal routers 434 individually connect the plurality of word line contacts 432 to the plurality of string driver contacts 430. As illustrated, the plurality of metal routers 434 extend parallel to the memory array 402.

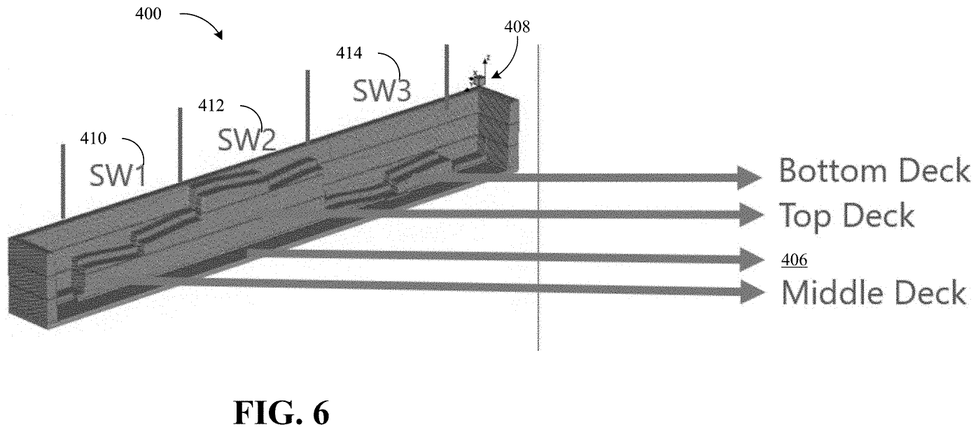

Additional details regarding parallel layout memory device 400 are discussed below with respect to FIG. 6.

FIG. 5 is a perspective view of a staircase area of the serial layout memory device 300. As illustrated, the serial layout memory device 300 is typically limited to a total of two stairwells (e.g., stairwells 310/312) per memory block. In such an example, every stairwell has word line contacts landing on each and every deck (e.g., a top deck, a middle deck, and a bottom deck in some implementations). Additionally, the stairwells 310/312 and through array vias (TAV 306) are placed in serial positions (e.g., where a TAV 306 is interspersed between each sequential pair of stairwells 310/312).

FIG. 6 is a perspective view of the staircase area 408 of the parallel layout memory device 400 according to an embodiment. As discussed above, the parallel layout memory device 400 differs from the serial layout memory device 300 in several ways. For example, the parallel layout memory device 400 includes more than two stairwells (e.g., the first stairwell 410, the second stairwell 412, and the third stairwell 414 in the illustrated example). Further, the first stairwell 410, the second stairwell 412, and the third stairwell 414 each have word line contacts that land on only one deck (e.g., one stairwell is associated with each of a top deck, a middle deck, and a bottom deck). Additionally, the first stairwell 410, the second stairwell 412, and the third stairwell 414 are placed side-by-side in parallel position to the TAV 406.

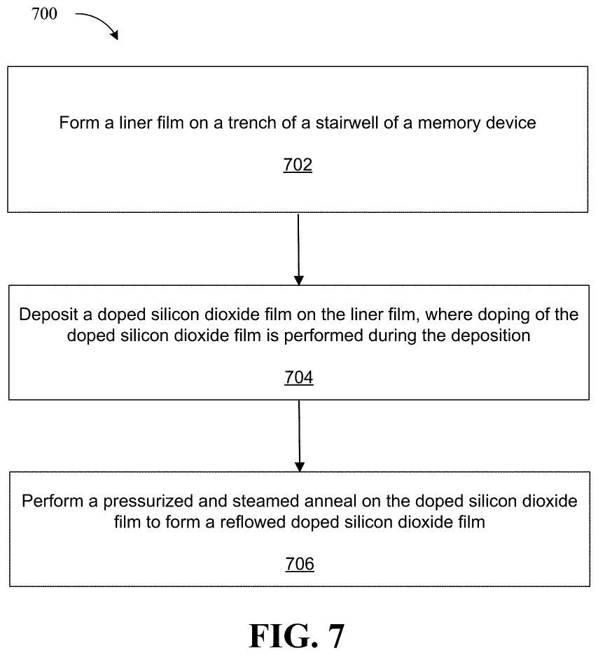

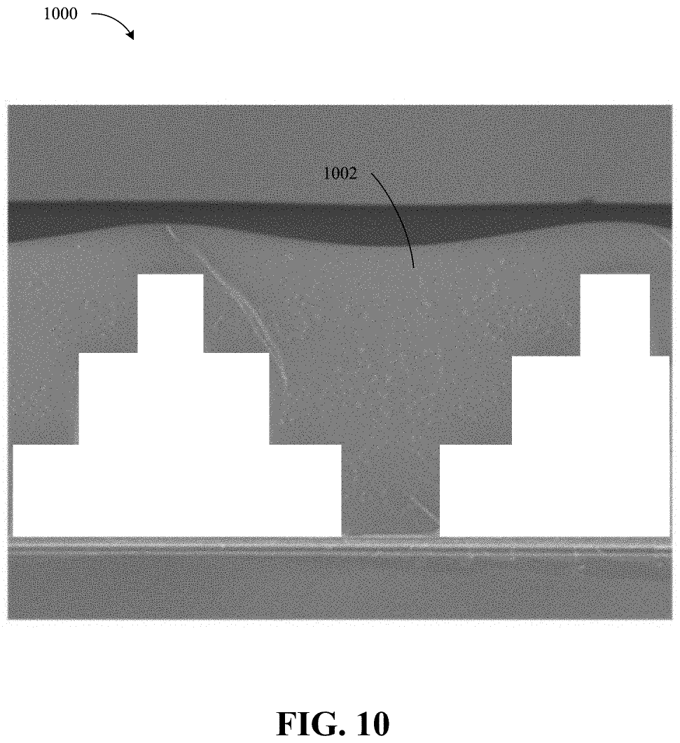

FIG. 7 is a flowchart of an example of a method 700 of forming a memory device according to an embodiment. The method 700 may generally be implemented to form a memory device, such as, for example, the memory device 1000 (e.g., see FIG. 10), discussed in more detail below.

Illustrated processing block 702 provides for forming a liner film on a trench of a stairwell layer of a memory device.

In some implementations, the liner film includes a silicon nitride (SiN) material, the liner film has a thickness ranging from 100 angstroms to 3000 angstroms, the liner film is to prevent diffusion into the stairwell layer of one or more of dihydrogen, oxygen, boron dopant, or phosphorus dopant, and/or the liner film is to be formed to avoid pinhole abnormalities at a temperature ranging from 500 degrees Celsius to 700 degrees Celsius.

Illustrated processing block 704 provides for depositing a doped silicon dioxide film on the liner film, wherein doping of the doped silicon dioxide film is performed during the deposition.

In some implementations, the doped silicon dioxide film is doped with 3% to 5% boron or phosphorus, the doped silicon dioxide film has a thickness ranging from 5 micrometers to 10 micrometers, the doped silicon dioxide film has a conformal deposition step coverage of greater than 50 percent, the doped silicon dioxide film has a deposition rate greater than 1 micrometer per minute, and/or the doped silicon dioxide film is deposited via a plasma enhanced chemical vapor deposition reactor at a temperature from 300 degrees Celsius to 550 degrees Celsius.

Illustrated processing block 706 provides for performing a pressurized and steamed anneal on the doped silicon dioxide film deposited on the liner film to form a reflowed doped silicon dioxide film

In some implementations, a pressure ranges from 20 atmospheres to 80 atmospheres during the pressurized and steamed anneal, a temperature of the pressurized and steamed anneal ranges from 650 degrees Celsius to 750 degrees Celsius, and/or the pressurized and steamed anneal includes utilization of water, oxygen, nitrogen, and dihydrogen.

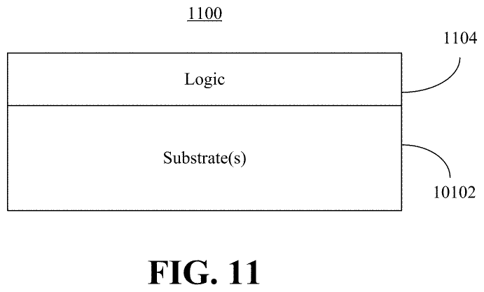

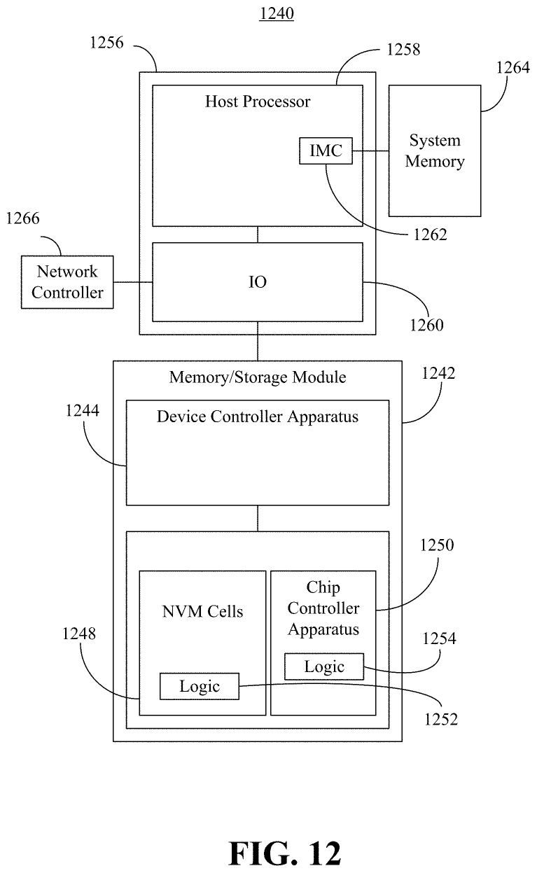

Additional details regarding the various implementations of method 700 are discussed below with regard to FIGS. 11 and 12.

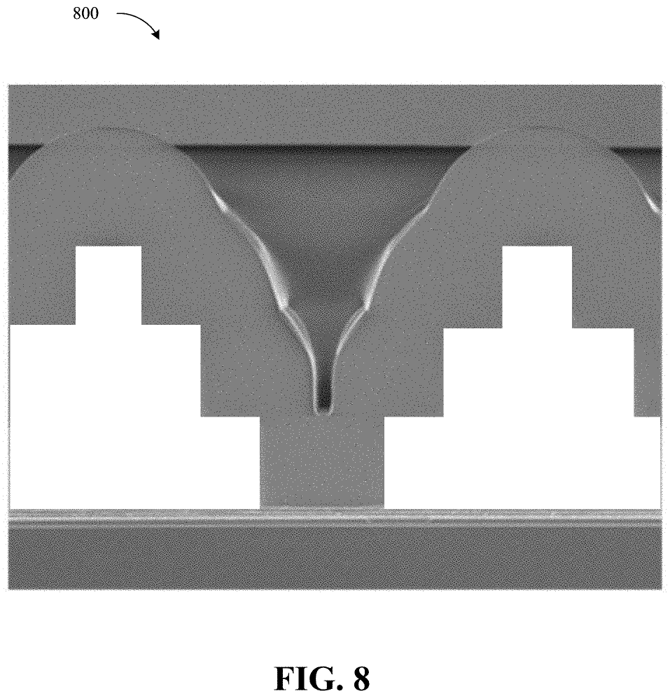

FIG. 8 shows an existing memory device 800 formed via an existing anneal process. As illustrated, the existing memory device 800 is formed via an existing anneal process, similar to those described above.

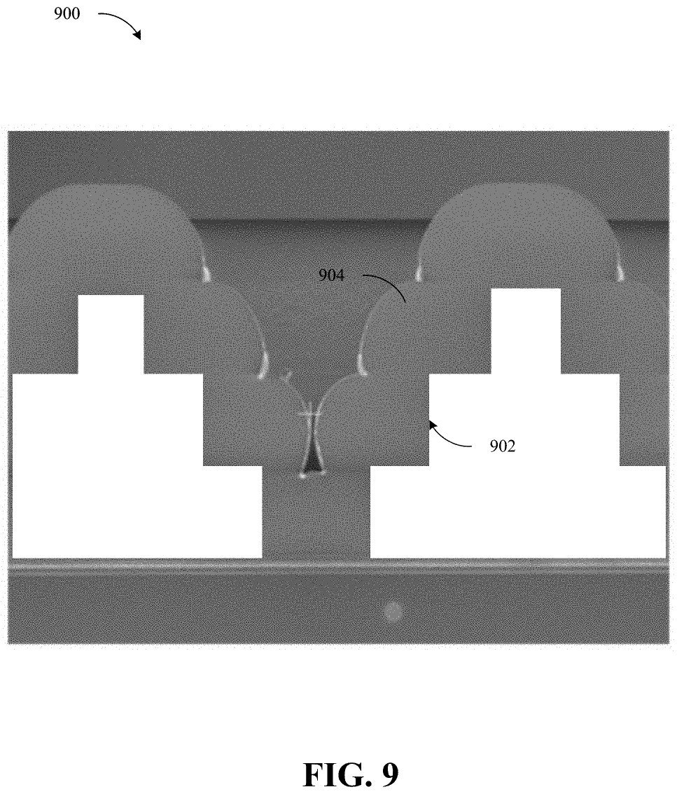

FIG. 9 shows a memory device 900 after deposition according to an embodiment. As illustrated, in some implementations, the illustrated memory device 900 includes a liner film 902 and a doped silicon dioxide (SiO2) film 904 are formed on a trench of the memory device 900.

In one implementation, a liner film 902 including a silicon nitride (SiN) material is introduced. Such a liner film 902 ranges from 100-3000 A with no pinhole abnormalities and good film quality at the temperature ranging from 500 degrees Celsius to 700 degrees Celsius. The liner film 902 layer prevents impurity diffusion into sublayer during thermal anneal process in the downstream, which can potentially cause silicon (Si) and/or metal film oxidation and CMOS reliability degradation. For example, the liner film prevents any impurity diffusion into sub-layer such as dihydrogen (H2), oxygen (O2), boron (B) dopant, phosphorus (P) dopant which can potentially cause silicon (Si) and/or metal layer oxidation and CMOS reliability degradation.

In some examples, the doped silicon dioxide film (SiO2) 904 is deposited on the liner film 902 as either a B doped or P doped film via Plasma Enhanced-Chemical Vapor Deposition (PE-CVD). The doped silicon dioxide (SiO2) film 904 has a thickness ranging from 5 micrometers to 10 micrometers without pinch-off. Additionally, or alternatively, the doped silicon dioxide (SiO2) film 904 has high deposition rate (>1 um/min), conformal deposition (step coverage >50%), and high concentration of B, P dopant (3-5%).

For example, 3-5% of a B, P doped SiO2 film is deposited in a plasma enhanced chemical vapor deposition reactor at a low temperature from around 300 degrees Celsius to 550 degrees Celsius, which enables good conformal deposition (e.g., step coverage >50%) and high throughput performance (e.g., deposition rate >1 um/min) (as shown in FIG. 9) with no reflow/as-deposited. As incorporating B, P dopant into the doped SiO2 film is done during deposition, uniform doping can be achieved. Thickness target can be determined by pinch-off point. A maximum thickness without pinch-off is typically desired.

FIG. 10 shows a memory device 1000 formed via a pressurized anneal process according to an embodiment. As illustrated, in some implementations, the illustrated memory device 1000 includes a reflowed doped SiO2 film 1002.

In one implementation, a reflowed doped SiO2 film 1002 is formed via a pressurized and steamed anneal. For example, such a pressurized and steamed anneal is performed at the following conditions: (a) a relatively lower temperature ranging from 650-750 C (vs. an existing anneal temperature for reflow typically being >850 C), (b) an anneal time <2 hrs, (c) a high pressure ranging from 20-80 atm, and (d) utilization of ambient water (H2O), oxygen (O2), nitrogen (N2), and/or dihydrogen (H2).

In some examples, a B, P doped PE-CVD SiO2 deposition is followed by a high pressure process that results in a void/seam free one-step gap-fill solution as well as a high throughput. In such an example, the B, P dopant ranges from 3 to 5% of the SiO2 film, which can maximize reflowability without generating defects (e.g., such as defects that typically occur in boron phosphate (BPO4)). Then, such a high pressure steam anneal enhances high reflowability and good gap-fill performance at a lower thermal energy and lower anneal time (e.g., at <750 C, 2 hrs) as compared to existing anneal techniques (e.g., typically done at >850 C, 4 hrs) as the dopant diffusivity increases significantly at the high pressure (20-80 atm), for example. Since the concentration of ambient such as O2 and H2O increases on the surface of the doped silicon dioxide film at such a high pressure regime, diffusivity of reactant into film bulk from surface necessarily increases, which enhances B, P dopant diffusion in bulk film and drives a good reflowability to improve gap-fill performance.

Such a pressurized and steamed anneal reflow of the doped silicon dioxide film results in filling up in the trench without any void or defect. The high pressure anneal process ranges from 20 to 80 atm to enables superior reflowability as compared to existing anneal processes (e.g., typically done at latm). The dopants can be diffused into the SiO2 bulk film by thermal energy during the anneal process. Using surface tension during dopant diffusion, significant film reflow can occur, which can eliminate void/seam defects and planarize the film on topo wafers.

FIG. 10 shows high pressure reflow process profile at the condition of 750 C, 25 atm of pressure with steam. Conversely, FIG. 8 shows an existing reflow process profile at the condition of 750 C, 1 atm of pressure. Such an existing anneal illustrated in FIG. 8 shows little reflow profile at the condition of 1 atm pressure at 750 C. However, a high pressure steam anneal illustrated in FIG. 10 shows significant improvement of gap-fill performance as well as planarization due to good reflowability as increasing dopant diffusivity by high pressure since diffusivity is a function of concentration of element at surface and thermal energy. As reducing anneal temperature and time with high pressure condition, CMOS performance impact can be minimized and anneal time can be reduced. Some implementations herein can be operated at a high pressure ranging from 20 to 80 atmosphere with H2O, O2, N2, H2 gas. In addition, a cost of a downstream integration process can be reduced due to the following: 1) by minimizing over burden at an array area by gap-fill thickness reduction, and 2) borophosphosilicate glass (BPSG) chemical mechanical polishing (CMP) rates can be increased by 30 to 50%, compared to existing SiO2 processes.

FIG. 11 shows a semiconductor apparatus 1100 (e.g., chip, die, and/or package). The illustrated apparatus 1100 includes one or more substrates 1102 (e.g., silicon, sapphire, gallium arsenide) and logic 1104 (e.g., transistor array and other integrated circuit/IC components) coupled to the substrate(s) 1102. In an embodiment, the logic 1104 implements one or more aspects of the memory device 1000 (e.g., see FIG. 10) and/or the method 700 (e.g., see FIG. 7), already discussed.

In one example, the logic 1104 includes transistor channel regions that are positioned (e.g., embedded) within the substrate(s) 1102. Thus, the interface between the logic 1104 and the substrate 1102 may not be an abrupt junction. The logic 1104 may also be considered to include an epitaxial layer that is grown on an initial wafer of the substrate 1102.

Turning now to FIG. 12, a performance-enhanced computing system 1240 is shown. In the illustrated example, a solid state drive (SSD) 1242 includes a device controller apparatus 1244 that is coupled to a NAND 1246. The illustrated NAND 1246 includes a memory device 1248 having a set of multi-level NVM cells and logic 1252 (e.g., transistor array and other integrated circuit/IC components coupled to one or more substrates containing silicon, sapphire and/or gallium arsenide), and a chip controller apparatus 1250 that includes logic 1254. The logic 1254 may include one or more of configurable or fixed-functionality hardware.

The illustrated system 1240 also includes a system on chip (SoC) 1256 having a host processor 1258 (e.g., central processing unit/CPU) and an input/output (I/O) module 1260. The host processor 1258 may include an integrated memory controller 1262 (WIC) that communicates with system memory 1264 (e.g., RAM dual inline memory modules/DIMMs). The illustrated IO module 1260 is coupled to the SSD 1242 as well as other system components such as a network controller 1266.

In some embodiments, the NAND 1246 implements one or more aspects of the memory device 1000 (e.g., see FIG. 10) and/or the method 700 (e.g., see FIG. 7), already discussed already discussed.

### ADDITIONAL NOTES AND EXAMPLES

Example 1 includes a memory device comprising a memory array and a memory block coupled to the memory array. The memory block comprising a stairwell including a trench and a reflowed doped silicon dioxide film coating the stairwell trench. The reflowed doped silicon dioxide film comprises: a liner film formed on the trench of the stairwell of the memory device; and a doped silicon dioxide film deposited on the liner film, wherein doping of the doped silicon dioxide film is performed during the deposition of the doped silicon dioxide film, wherein the reflowed doped silicon dioxide film is formed through a pressurized and steamed anneal performed on the doped silicon dioxide film.

Example 2 includes the memory device of Example 1, wherein the liner film includes a silicon nitride (SiN) material.

Example 3 includes the memory device of any one of Examples 1 to 2, wherein the liner film has a thickness ranging from 100 angstroms to 3000 angstroms.

Example 4 includes the memory device of any one of Examples 1 to 3, wherein the liner film is to prevent diffusion into the stairwell layer of one or more of dihydrogen, oxygen, boron dopant, or phosphorus dopant.

Example 5 includes the memory device of any one of Examples 1 to 4, wherein the liner film is to be formed to avoid pinhole abnormalities at a temperature ranging from 500 degrees Celsius to 700 degrees Celsius.

Example 6 includes the memory device of any one of Examples 1 to 5, wherein the doped silicon dioxide film is doped with 3% to 5% boron or phosphorus.

Example 7 includes the memory device of any one of Examples 1 to 6, wherein the doped silicon dioxide film has a thickness ranging from 5 micrometers to 10 micrometers.

Example 8 includes the memory device of any one of Examples 1 to 7, wherein the doped silicon dioxide film has a conformal deposition step coverage of greater than 50 percent.

Example 9 includes the memory device of any one of Examples 1 to 8, wherein the doped silicon dioxide film has a deposition rate greater than 1 micrometer per minute.

Example 10 includes the memory device of any one of Examples 1 to 9, wherein the doped silicon dioxide film is deposited via a plasma enhanced chemical vapor deposition reactor at a temperature from 300 degrees Celsius to 550 degrees Celsius.

Example 11 includes the memory device of any one of Examples 1 to 10, wherein a pressure ranges from 20 atmospheres to 80 atmospheres during the pressurized and steamed anneal.

Example 12 includes the memory device of any one of Examples 1 to 11, wherein a temperature of the pressurized and steamed anneal ranges from 650 degrees Celsius to 750 degrees Celsius.

Example 13 includes the memory device of any one of Examples 1 to 12, wherein the pressurized and steamed anneal includes utilization of water, oxygen, nitrogen, and dihydrogen.

Example 14 includes a system comprising a memory controller and a multi-deck non-volatile memory structure coupled to the memory controller. The multi-deck non-volatile memory structure comprising a memory array and a memory block coupled to the memory array. The memory block comprising a stairwell including a trench and a reflowed doped silicon dioxide film coating the stairwell trench. The reflowed doped silicon dioxide film comprises: a liner film formed on the trench of the stairwell of the memory device; and a doped silicon dioxide film deposited on the liner film, wherein doping of the doped silicon dioxide film is performed during the deposition of the doped silicon dioxide film, wherein the reflowed doped silicon dioxide film is formed through a pressurized and steamed anneal performed on the doped silicon dioxide film.

Example 15 includes the system of Example 14, wherein the liner film includes a silicon nitride (SiN) material, wherein the liner film has a thickness ranging from 100 angstroms to 3000 angstroms, wherein the liner film is to prevent diffusion into the stairwell layer of one or more of dihydrogen, oxygen, boron dopant, or phosphorus dopant, and wherein the liner film is to be formed to avoid pinhole abnormalities at a temperature ranging from 500 degrees Celsius to 700 degrees Celsius.

Example 16 includes the system of any one of Examples 14 to 15, wherein the doped silicon dioxide film is doped with 3% to 5% boron or phosphorus, wherein the doped silicon dioxide film has a thickness ranging from 5 micrometers to 10 micrometers, wherein the doped silicon dioxide film has a conformal deposition step coverage of greater than 50 percent, wherein the doped silicon dioxide film has a deposition rate greater than 1 micrometer per minute, and wherein the doped silicon dioxide film is deposited via a plasma enhanced chemical vapor deposition reactor at a temperature from 300 degrees Celsius to 550 degrees Celsius.

Example 17 includes the system of any one of Examples 14 to 16, wherein a pressure ranges from 20 atmospheres to 80 atmospheres during the pressurized and steamed anneal, wherein a temperature of the pressurized and steamed anneal ranges from 650 degrees Celsius to 750 degrees Celsius, and wherein the pressurized and steamed anneal includes utilization of water, oxygen, nitrogen, and dihydrogen.

Example 18 includes a method comprising: forming a liner film on a trench of a stairwell layer of a memory device; depositing a doped silicon dioxide film on the liner film, wherein doping of the doped silicon dioxide film is performed during the deposition; and performing a pressurized and steamed anneal on the doped silicon dioxide film deposited on the liner film to form a reflowed doped silicon dioxide film.

Example 19 includes the method of Example 18, wherein the liner film includes a silicon nitride (SiN) material, wherein the liner film has a thickness ranging from 100 angstroms to 3000 angstroms, wherein the liner film is to prevent diffusion into the stairwell layer of one or more of dihydrogen, oxygen, boron dopant, or phosphorus dopant, wherein the liner film is to be formed to avoid pinhole abnormalities at a temperature ranging from 500 degrees Celsius to 700 degrees Celsius, wherein the doped silicon dioxide film is doped with 3% to 5% boron or phosphorus, wherein the doped silicon dioxide film has a thickness ranging from 5 micrometers to 10 micrometers, wherein the doped silicon dioxide film has a conformal deposition step coverage of greater than 50 percent, wherein the doped silicon dioxide film has a deposition rate greater than 1 micrometer per minute, and wherein the doped silicon dioxide film is deposited via a plasma enhanced chemical vapor deposition reactor at a temperature from 300 degrees Celsius to 550 degrees Celsius.

Example 20 includes the method of any one of Examples 18 to 19, wherein a pressure ranges from 20 atmospheres to 80 atmospheres during the pressurized and steamed anneal, wherein a temperature of the pressurized and steamed anneal ranges from 650 degrees Celsius to 750 degrees Celsius, and wherein the pressurized and steamed anneal includes utilization of water, oxygen, nitrogen, and dihydrogen.

Example 21 includes an apparatus comprising means for performing the method of any one of Examples 18 to 20.

Example 22 includes a machine-readable storage comprising machine-readable instructions, which when executed, implement a method or realize an apparatus as claimed in any preceding claim.

Technology described herein therefore advantageously provides the capability to utilize doped (e.g., doped via a p-type dopant (e.g., boron (b)) or an n-type dopant (e.g., phosphorus (P))) silicon dioxide (SiO2) followed by high pressure anneal (HPA) reflow process. Such technology advantageously provides the following: 1) a gap-fill performance improvement (e.g., a void/seam free gap-fill solution at high aspect ratio and big volume of staircase trench), 2) a cost reduction including a 1 step gap-fill simple process, 3) a cost reduction including a borophosphosilicate glass (BPSG) chemical mechanical polishing (CMP) rate increase by 30%, 4) a cost reduction including a gap-fill thickness target reduction which reduces deposition and overburden planarization, and 5) a minimum impact on complementary metal-oxide-semiconductor (CMOS) performance by HPA anneal process as lowering anneal temperature (e.g., from >850 degrees C. at existing anneal techniques) to <750 degrees C. at HPA utilizing the techniques described herein.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A memory device comprising:
a memory array; and
a memory block coupled to the memory array, the memory block comprising:
a stairwell including a trench; and
a reflowed doped silicon dioxide film coating the stairwell trench, wherein the reflowed doped silicon dioxide film comprising:
a liner film formed on the trench of the stairwell of the memory device; and
a doped silicon dioxide film deposited on the liner film, wherein doping of the doped silicon dioxide film is performed during the deposition of the doped silicon dioxide film,
wherein the reflowed doped silicon dioxide film is formed through a pressurized and steamed anneal performed on the doped silicon dioxide film.

2. The memory device of claim 1, wherein the liner film includes a silicon nitride (SiN) material.

3. The memory device of claim 1, wherein the liner film has a thickness ranging from 100 angstroms to 3000 angstroms.

4. The memory device of claim 1, wherein the liner film is to prevent diffusion into the stairwell layer of one or more of dihydrogen, oxygen, boron dopant, or phosphorus dopant.

5. The memory device of claim 1, wherein the liner film is to be formed to avoid pinhole abnormalities at a temperature ranging from 500 degrees Celsius to 700 degrees Celsius.

6. The memory device of claim 1, wherein the doped silicon dioxide film is doped with 3% to 5% boron or phosphorus.

7. The memory device of claim 1, wherein the doped silicon dioxide film has a thickness ranging from 5 micrometers to 10 micrometers.

8. The memory device of claim 1, wherein the doped silicon dioxide film has a conformal deposition step coverage of greater than 50 percent.

9. The memory device of claim 1, wherein the doped silicon dioxide film has a deposition rate greater than 1 micrometer per minute.

10. The memory device of claim 1, wherein the doped silicon dioxide film is deposited via a plasma enhanced chemical vapor deposition reactor at a temperature from 300 degrees Celsius to 550 degrees Celsius.

11. The memory device of claim 1, wherein a pressure ranges from 20 atmospheres to 80 atmospheres during the pressurized and steamed anneal.

12. The memory device of claim 1, wherein a temperature of the pressurized and steamed anneal ranges from 650 degrees Celsius to 750 degrees Celsius.

13. The memory device of claim 1, wherein the pressurized and steamed anneal includes utilization of water, oxygen, nitrogen, and dihydrogen.

14. A system comprising:
a memory controller; and
a multi-deck non-volatile memory structure coupled to the memory controller, the multi-deck non-volatile memory structure comprising:
a memory array; and
a memory block coupled to the memory array, the memory block comprising:
a stairwell including a trench; and
a reflowed doped silicon dioxide film coating the stairwell trench, wherein the reflowed doped silicon dioxide film comprising:
a liner film formed on the trench of the stairwell of the memory device; and
a doped silicon dioxide film deposited on the liner film, wherein doping of the doped silicon dioxide film is performed during the deposition of the doped silicon dioxide film,
wherein the reflowed doped silicon dioxide film is formed through a pressurized and steamed anneal performed on the doped silicon dioxide film.

15. The system of claim 14, wherein the liner film includes a silicon nitride (SiN) material,
wherein the liner film has a thickness ranging from 100 angstroms to 3000 angstroms,
wherein the liner film is to prevent diffusion into the stairwell layer of one or more of dihydrogen, oxygen, boron dopant, or phosphorus dopant, and
wherein the liner film is to be formed to avoid pinhole abnormalities at a temperature ranging from 500 degrees Celsius to 700 degrees Celsius.

16. The system of claim 14, wherein the doped silicon dioxide film is doped with 3% to 5% boron or phosphorus,
wherein the doped silicon dioxide film has a thickness ranging from 5 micrometers to 10 micrometers,
wherein the doped silicon dioxide film has a conformal deposition step coverage of greater than 50 percent,
wherein the doped silicon dioxide film has a deposition rate greater than 1 micrometer per minute, and
wherein the doped silicon dioxide film is deposited via a plasma enhanced chemical vapor deposition reactor at a temperature from 300 degrees Celsius to 550 degrees Celsius.

17. The system of claim 14, wherein a pressure ranges from 20 atmospheres to 80 atmospheres during the pressurized and steamed anneal,
wherein a temperature of the pressurized and steamed anneal ranges from 650 degrees Celsius to 750 degrees Celsius, and
wherein the pressurized and steamed anneal includes utilization of water, oxygen, nitrogen, and dihydrogen.

18. A method comprising:
forming a liner film on a trench of a stairwell layer of a memory device;
depositing a doped silicon dioxide film on the liner film, wherein doping of the doped silicon dioxide film is performed during the deposition; and
performing a pressurized and steamed anneal on the doped silicon dioxide film deposited on the liner film to form a reflowed doped silicon dioxide film.

19. The method of claim 18, wherein the liner film includes a silicon nitride (SiN) material,
wherein the liner film has a thickness ranging from 100 angstroms to 3000 angstroms,
wherein the liner film is to prevent diffusion into the stairwell layer of one or more of dihydrogen, oxygen, boron dopant, or phosphorus dopant,
wherein the liner film is to be formed to avoid pinhole abnormalities at a temperature ranging from 500 degrees Celsius to 700 degrees Celsius, wherein the doped silicon dioxide film is doped with 3% to 5% boron or phosphorus,
wherein the doped silicon dioxide film has a thickness ranging from 5 micrometers to 10 micrometers,
wherein the doped silicon dioxide film has a conformal deposition step coverage of greater than 50 percent,
wherein the doped silicon dioxide film has a deposition rate greater than 1 micrometer per minute, and
wherein the doped silicon dioxide film is deposited via a plasma enhanced chemical vapor deposition reactor at a temperature from 300 degrees Celsius to 550 degrees Celsius.

20. The method of claim 18, wherein a pressure ranges from 20 atmospheres to 80 atmospheres during the pressurized and steamed anneal,
wherein a temperature of the pressurized and steamed anneal ranges from 650 degrees Celsius to 750 degrees Celsius, and
wherein the pressurized and steamed anneal includes utilization of water, oxygen, nitrogen, and dihydrogen.
